(19) United States
(12) Patent Application Publication
(10) Pub. No.: US 2006/0240579 A1
(43) Pub. Date: Oct. 26, 2006

(54) Method for reducing threshold voltage variations due to gate length differences

(75) Inventor: Ju-Hsin Chi, Taichung County (TW)

Correspondence Address: BIRCH STEWART KOLASCH & BIRCH, PO BOX 747, FALLS CHURCH, VA, 22040-0747, US

(73) Assignee: Powerchip Seminconductor Corp.

(21) Appl. No.: 11/228,199

(22) Filed: Sep. 19, 2005

(30) Foreign Application Priority Data
Apr. 21, 2005 (TW) 94112690

(51) Int. Cl. H01L 21/00

(52) U.S. Cl. 438/5

(57) ABSTRACT

The invention provides a method of reducing threshold voltage variations due to gate length differences. The method comprises: providing a substrate having a plurality of MOS transistors at different gate lengths, pocket implanting these MOS transistors at different angles, establishing a relationship between the threshold voltages and gate lengths on the different implant angles to determine an angle with minimal threshold voltage variation for next implantation.

### BACKGROUND

The invention relates to a method for reducing threshold voltage variations due to different gate lengths, and more particularly to a method for reducing threshold voltages caused by gate length difference in a highly concentrated area of transistor, such as a memory unit of RAM, by means of ion implantation.

Threshold voltage, a significant parameter in MOS transistors, represents applying a voltage to gate appropriate for turning on the transistor. In order to obtain transistors with similar current and voltage characteristics, so as to electrically match individual transistors with identical power supply in an integrated circuit, threshold voltage adjustment is necessary.

Threshold voltage relates to the quality of a gate dielectric layer, and more particularly to gate length L, as shown in formula (1):
Vₜₕ=m×L+n (1)

wherein m and n are constant, and m is greater than zero. Due to being affected by the flatness of a wafer surface, mask, deposition of thin film lithography, and etching processes, the subsequently formed transistor gate lengths are not uniform. Nevertheless, gate length can be held within an acceptable range under strictly controlled process parameters. According to formula (1), the smaller the transistor is, the smaller the gate length is. Additionally, threshold voltage decreases due to both factors. When a transistor is restricted to a predetermined size, however, threshold voltage variation will be out of range due to gate length variation.

With gate length shrinkage, to avoid the decreasing controllability of the channel by gate length due to the short channel effect, a method of circle implantation, such as pocket implantation or halo implantation, is widely used. As for tilt-angle punch-through stoppers (TIPS), the implant region thereof deposited on a source/drain near the edge of the transistors, or alternatively surrounding the source/drain, with reduced junction punch through, reduced off current (Ioff), and increase in threshold voltage. Observed results of limiting short channel effects by utilizing different circle implant conditions, show that although transistors with circle implantation can improve the short channel effect, reversed short channel effect (RSCE) can be generated due to high implantation in the channel.

Implantation plays a considerably significant role in integrated circuit manufacturing, and the major application thereof comprises formation of wells and source/drain, prevention of junction punch-through, and adjustment of transistor threshold voltage. However, simple ion implantation still cannot improve threshold voltage variation caused by gate length differences in transistors.

### SUMMARY

Accordingly, the invention provides a method of reducing threshold voltages variation due to gate length difference.

One feature of the invention provides a method of automatic feedback of transistor threshold voltages, which can compensate for threshold voltage variation caused by gate length difference to obtain uniform transistor threshold voltages.

To achieve the above, the invention also provides a method for reducing threshold voltages caused by gate length difference in a highly concentrated transistor area, such as a memory unit of RAM, by means of ion implantation.

The invention further provides a method of reducing transistor sheet resistance and improving saturated drain current (Ids).

To achieve the above, the invention also provides a method for automatically compensating threshold voltage variation caused by gate length difference to obtain uniform transistor threshold voltages by utilizing implantation with different angles and the shadowing effect of the neighboring transistors. The methods comprises the following steps: providing a substrate having a plurality of MOS transistors with different gate lengths, performing a pocket implantation at different angles in said MOS transistors, establishing a correlation between the threshold voltages and the gate lengths versus the different implant angles to determine an angle with minimal threshold voltage variation for subsequent implantation.

### DESCRIPTION OF THE DRAWINGS

The invention will become more fully understood from the detailed description given hereinbelow and the accompanying drawings, given by way of illustration only and thus not intended to be limitative of the present invention.

FIG. 1 illustrates an embodiment of a method for reducing threshold voltage variations due to gate length differences according to one embodiment of the invention.

FIG. 2 illustrates a process of ion implantation while the ion implantation with the insufficient angle is applied.

FIG. 3 illustrates the correlation between the gate length and threshold voltage of the MOS transistors in a memory unit of a RAM by performing ion implantation due to different angles.

FIG. 4 illustrates the correlation between the saturated drain current and threshold voltage of the MOS transistors in a memory unit of a RAM by performing ion implantation due to different angles.

### DETAILED DESCRIPTION

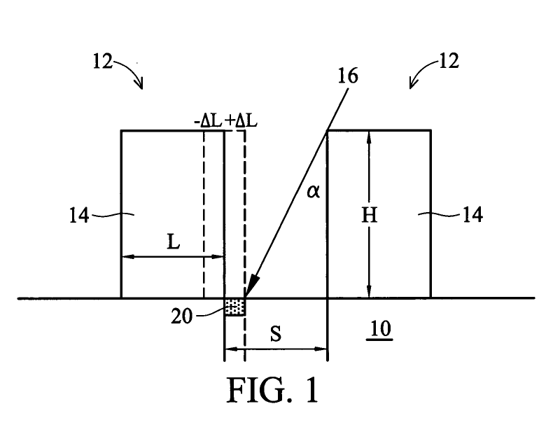

FIG. 1 illustrates an exemplary embodiment of a method for reducing threshold voltage variations due to gate length differences. A semiconductor substrate is provided, preferably a silicon substrate. A plurality of MOS transistors 12 arranged in arrays are then formed on the semiconductor substrate 10, wherein the heights of the MOS transistors 12 are H, and the actual length(s) of the gate(s) 14 are L. Ideally, the actual length(s) L of the gate 14 are equal to target lengths. Furthermore, a space S exists between each MOS transistor 12.

Ion implantation step 16 is performed to form a pocket implant region 20 to adjust the threshold voltage Vth of the transistor. The direction of ion implantation 16 crosses normal vectors of the substrate by an angle α. The MOS transistor 12, utilized as a shield for ion implantation, efficiently preventing the ion implantation regions approaching the edge of the gate 14 of the MOS transistor. The the threshold voltage Vth of the transistor with ion implantation is represented by the following formula (I):
Vₜₕ=a×L′+b×(S−H×tan α)+c (I)

wherein a, b, and c are constant, and a and b are both greater than zero. Moreover, a×L′ represents the impact of the threshold voltage by gate lenth, and b×(S−H×tanα) means the impact of the threshold voltage by ion implantation. Not only sheet resistance (Rs) of the transistor can be reduced but improved saturated drain current (Ids) can be obtained after performing the ion implantation.

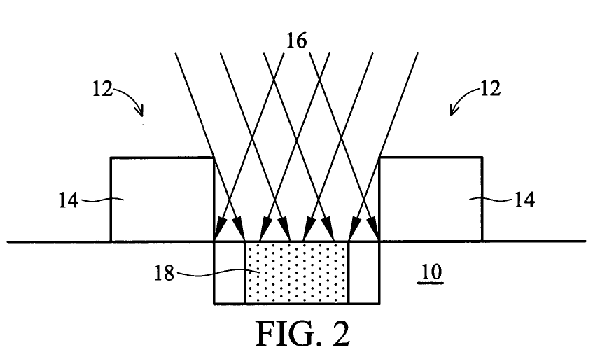

Referring to FIG. 2, when ion implantation with an insufficient angle is applied and the area of gate 14 of nearby MOS transistor 12 cannot be adequately shielded, the implantation region will be formed between the neighboring MOS transistors 12. Thus, it can be seen that the threshold voltage of MOS transistor 12 correlates with the gate length of MOS transistor 12. An overlapping portion 18 is formed between the neighboring transistors 12, therefore, it results in considerably high charge concentration exists on the surface of the substrate underlying the overlapping portion 18, in addition, the junction leakage current increases, which means the charge of capacitor rapidly decreases. Thus, increased refresh frequency is further required.

Accordingly, the angle α of ion implantation can be estimated by the space S between the MOS transistors 12 and height H thereof to obtain an adequate angle. Besides, a plurality of ion implantation at different angles are further utilized to perform in MOS transistor 12, and the threshold voltage of MOS semiconductor 12 are measured to establish a correlation between the threshold voltages and the gate lengths versus the different implant angles to determine an angle with minimal threshold voltage variation by gate length difference.

When the acrual gate length L of each transistor 12 is within the range +/−ΔL of gate length variation, the threshold voltage Vth which varies with it is represented as formula (II):
Vth′=a×(L′+/−ΔL)+b×[S−(L′+/−ΔL)−H×tan α]+c (II)
ΔVₜₕ=Vₜₕ′−Vₜₕ=a×(+/−ΔL)+b×[−(+/−ΔL)] (III)

Referring to formula (III), a or b is more than zero, resulting from the realistic length L of gate 14 of each transistor 12 within the range +/−ΔL of the gate length variation, therefore, b×[−(+/−ΔL)] is automatically fed back to a×(+/−ΔL) regardless of whether ΔL is positive or negative. Thus, threshold voltage variations caused by gate length differences of the MOS transistor 12 are reduced, furthermore, the threshold voltage of MOS transistor 12 is more uniform.

Threshold voltage is adjusted by utilizing known ion implantation with different gate lengths. Nevertheless, in the invention, the appropriate ion dopant is determined, afterwards, an adequate implant angle is obtained for an individual product and then automatically fed back for processing as formula (III) to lower the threshold voltage variations caused by gate length differences and force the threshold voltage of MOS transistor 12 to be uniform.

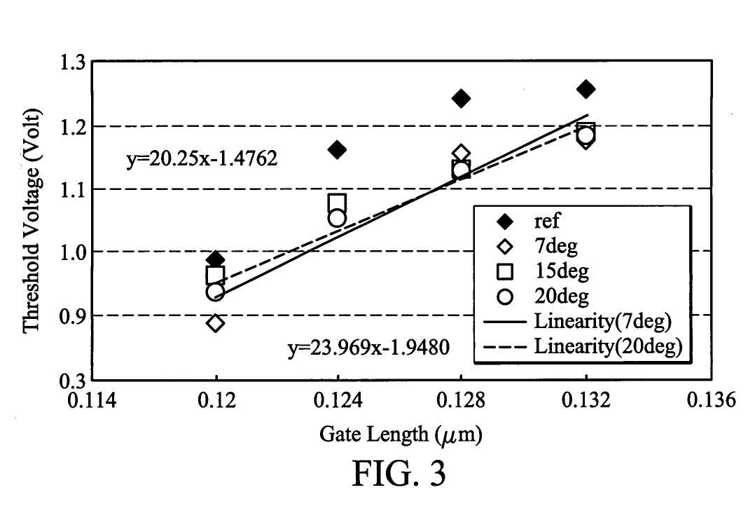

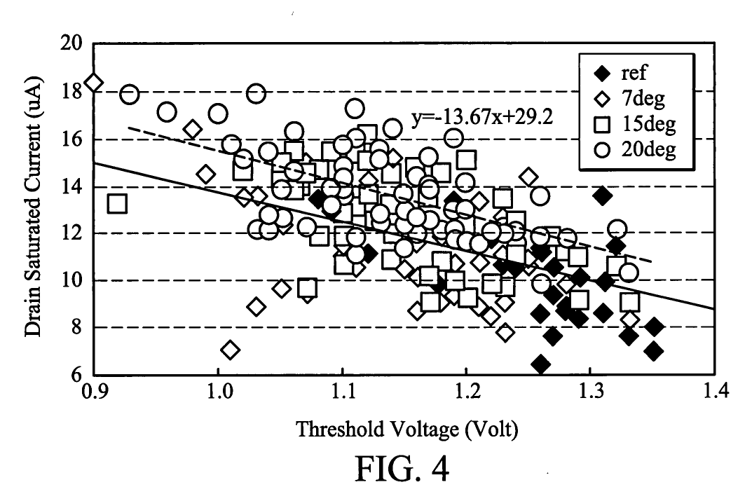

FIG. 3 and FIG. 4 show, the correlation between the gate length and threshold voltage of the MOS transistors in a memory unit of a RAM obtained by performing ion implantation at different angles and the correlation between the saturated drain current and threshold voltage. Boron implantation at implant angles of 7, 15, and 20 degrees are performed on the MOS transistor with a gate height of 270 nm and a gate length of 130 nm, wherein the space between the neighboring MOS transistors is 130 nm. According to the results from FIG. 3 and FIG. 4, it concludes that the correlation between the gate length and threshold voltage, and the saturated drain current and threshold voltage of the MOS transistors in a memory unit of a RAM by performing ion implantation at different angles, compared with original process of performing implantation before forming the gate, is thus improved. Preferably, ion implantation at an angle of 20 degree provides the greatest improvement, which is attributable to utilizing the shielding effect of the neighboring MOS transistors to automatically generate the gate length variation feedback.

Accordingly, the correlation between the gate length and threshold voltage of the MOS transistors by performing ion implantation at different angles relying on the method recited above is constructed. Thus, pocket implantation can be performed on the MOS transistor with formed gate and source/drain by the preferable implant angle above to obtain the transistors with uniform threshold voltage. Take a RAM of 0.13 μm as an example, the preferable implantation angle is generally between around 10-22 degrees. However, to those skilled in the art, it is to be understood that the preferable implant angle varies with different gate lengths and parameters of the process and the invention are not limited to the specific angle.

Threshold voltage of MOS transistor is automatically fed back by utilizing the shielding effect of the transistors and implantation at different angles of the invention. Accordingly, threshold voltage variation caused by gate length difference is made uniform. However, threshold voltage variation caused by gate length difference worsens followed when gate length shrinkage, therefore, the invention provides a promising function for processes lower than 0.15 μm, particularly for RAM where the space between the transistors is less than 130 nm.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A method for reducing threshold voltage variations due to gate length differences, comprising:
providing a substrate having a plurality of MOS transistors with different gate lengths and threshold voltages, performing a pocket implantation at different implant angles in the MOS transistors, and
establishing a correlation between the threshold voltages and the gate lengths versus the different implant angles to determine an optimum angle with minimal threshold voltage variation for subsequent implantation.

2. The method as claimed in claim 1, further comprising forming a memory unit of random access memory (RAM) from the MOS transistors and capacitors.

3. The method as claimed in claim 1, wherein the pocket implantation comprises boron implantation.

4. The method as claimed in claim 1, wherein the implant angles are around 10-22 degrees.

5. The method as claimed in claim 1, wherein the MOS transistors are arranged in array.

6. The method as claimed in claim 1, wherein the gate lengths of the MOS transistors are less than 150 nm.

7. The method as claimed in claim 1, wherein spaces between the MOS transistors are less than 130 nm.
